(19) United States
(12) Patent Application Publication
(10) Pub. No.: US 2026/0344022 A1
(43) Pub. Date: Oct. 29, 2026

(54) GROUP III NITRIDE TRANSISTOR DEVICE

(71) Applicant: Infineon Technologies Austria AG, Villach (AT)

(72) Inventors: Saurabh Roy, Villach (AT); Andressa Colvero Schittler, Ense, Niederense (DE); Diana Katharina Mann, Arnoldstein (AT); Marcus Böhm, Mintraching (DE)

(21) Appl. No.: 19/657,099

(22) Filed: Apr. 24, 2026

(30) Foreign Application Priority Data
Apr. 24, 2025 (DE) 102025115907.6

(51) Int. Cl. H10D 84/80; H10D 1/47; H10D 30/47; H10W 20/41; H10W 20/43; H10D 1/00; H10D 30/01; H10D 62/824

(52) U.S. Cl. CPC H10D 84/817; H10D 1/474; H10D 30/475; H10W 20/43; H10W 20/435; H10D 1/021; H10D 30/015; H10D 30/477; H10D 62/824

(57) ABSTRACT

In an embodiment, a Group III nitride transistor device is provided that includes: a Group III nitride body having an active area that contributes to load switching, a Group III nitride channel layer and a Group III nitride barrier layer that is arranged on the Group III nitride channel layer and forms a heterojunction therebetween; a source finger, a gate finger and a drain finger arranged on the Group III nitride barrier layer; a source pad electrically coupled to the source finger; a gate pad electrically coupled to the gate finger; a drain pad electrically coupled to the drain finger; and a gate resistor electrically coupled between the gate pad and gate finger of the transistor device. The gate resistor is located at least partially on the active area of the transistor device.

### BACKGROUND

To date, transistors used in power electronic applications have typically been fabricated with silicon (Si) semiconductor materials. Common transistor devices for power applications include Si CoolMOS®, Si Power MOSFETs, and Si Insulated Gate Bipolar Transistors (IGBTs). More recently, silicon carbide (SiC) power devices have been considered. Group III-N semiconductor devices, such as gallium nitride (GaN) devices, are now emerging as attractive candidates to carry large currents, support high voltages and to provide very low on-resistance and fast switching times.

Published US patent application US 2016/0211337 A1 describes a Group III-nitride power device including a HEMT (High Electron Mobility Transistor) with multiple interconnect metal layers and a solderable front metal structure using solder bars for external circuit connections. The solderable front metal structure may comprise a tri-metal such as TiNiAg, and may be configured to provide the source and drain contacts of the HEMT as alternating elongated digits or bars.

It is desirable to provide Group III nitride-based transistor devices which have a compact size and which can be more easily integrated into applications.

### SUMMARY

In an embodiment, a Group III nitride transistor device is provided that comprises a Group III nitride body comprising an active area that contributes to load switching, a Group III nitride channel layer and a Group III nitride barrier layer that is arranged on the Group III nitride channel layer and forms a heterojunction therebetween, a source finger, a gate finger and a drain finger arranged on the Group III nitride barrier layer, a source pad electrically coupled to the source finger, a gate pad electrically coupled to the gate finger and a drain pad electrically coupled to the drain finger and a gate resistor electrically coupled between the gate pad and gate finger of the transistor device. The gate resistor is located at least partially on the active area of the transistor device.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIG. 1A illustrates a schematic perspective view and FIG. 1B illustrates a schematic cross-sectional view of a portion of a Group III nitride transistor device.

FIG. 2A illustrates a schematic top view and FIG. 2B illustrates a schematic cross-sectional view of a frontside metallisation structure of a Group III nitride transistor device according to an embodiment.

FIGS. 3A-3C illustrate a method for fabricating a Group III nitride transistor device.

FIG. 4A illustrates a schematic perspective view and FIG. 4B illustrates a schematic cross-sectional view of a Group III nitride transistor device according to an embodiment.

FIGS. 5A-5D illustrate a method for fabricating a gate resistor in a groove formed in the second major surface of the support substrate of a Group III nitride transistor device.

FIG. 6 Illustrates a Group III nitride transistor device according to an embodiment.

FIG. 7 Illustrates a top view of a Group III nitride device according to an embodiment.

### DETAILED DESCRIPTION

In the following detailed description, reference is made to the accompanying drawings, which form a part thereof, and in which is shown by way of illustration specific embodiments in which the invention may be practiced. In this regard, directional terminology, such as "top", "bottom", "front", "back", "leading", "trailing", etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, "lateral" or "lateral direction" should be understood to mean a direction or extent that runs generally parallel to the lateral extent of a semiconductor material or semiconductor carrier. The lateral direction thus extends generally parallel to these surfaces or sides. In contrast thereto, the term "vertical" or "vertical direction" is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A depletion-mode device, such as a high-voltage depletion-mode transistor, has a negative threshold voltage which means that it can conduct current at zero gate voltage. These devices are normally on. An enhancement-mode device, such as a low-voltage enhancement-mode transistor, has a positive threshold voltage which means that it cannot conduct current at zero gate voltage and is normally off.

As used herein, the phrase "Group III-Nitride" refers to a compound semiconductor that includes nitrogen (N) and at least one Group III element, including aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), and aluminum indium gallium arsenide phosphide nitride (AlₓIn_{y}Ga_{(1-x-y)}AsₐP_{b}N_{(1-a-b)}), for example. Aluminum gallium nitride and AlGaN refers to an alloy described by the formula AlₓGa₍₁₋ₓ₎N, where 0 < x < 1.

For a Group III nitride High Electron Mobility Transistor (HEMT) proper thermal management strategy at the chip level alleviates the impact of any self-heating of the two-dimensional electron gas (2DEG), increases the reliability, boosts the output power, and widens the safe operating area of the device.

When aiming for a higher operating voltage, lateral GaN devices may have an enlarged chip size. When such devices are integrated in a module, a substantial space within the module is occupied by wire bonds to the source/drain-gate contacts. For a pre-defined package, this may limit the power densities of the package.

Alternative to the approach of wire bonding Group III nitride-based devices, face down mounting of the chips may be used, e.g. using a bump technique. The flip chip bumps play several roles including electrical connection, thermal connection and mechanical robustness. To enhance the heat transfer capability, the bumps are mounted on the exterior surface of the transistor. If the gate, source and drain contacts are placed on the single side of the device, this may reduce the heat dissipation rate. With the flip chip approach, the solder bumps or Cu pillars on the gate, drain and the source pads are the only conduction ways to transfer heat to the base plate. Therefore, the channel heat is moved from the gates through two distinct paths, namely the Group III nitride and the underlying Si substrate. Since both have similar thermal conductivity, most of the channel heat passes though the bumps. Three parameters of a thermal bump are its cross-sectional area, its height, and its material. The effective cross section of the bumps may be a limiting parameter because of the current crowding phenomena, for example for GaN power devices designed to block higher voltages, e.g. greater than 650V.

One approach to mitigate these issues proposed in the present disclosure is to place the source and drain contacts on opposing sides of the chip. Alternatively, or in addition, gate structures which are disposed into layers above or below, but not within, active portions (that is the 2-DEG layer) of the chips are proposed in the present disclosure. As such, the commonly inherent design limitation of space competing HEMT- and gate resistors within the 2-DEG layer is mitigated. Greater portions of the active area with its 2-DEG can be occupied by HEMT structures. This may be used to provide a reduced chip R_{DS,on}, while retaining the same die size, or to realize a chip shrink for a given R_{DS,on}.

Further embodiments of the invention provide semiconductor structures or devices having one or more gate contact structures (e.g. one or more gate contact vias) disposed over active portions of the gate electrode of the semiconductor structures or devices.

The present invention also provides a gate contact structure including the gate pad and an additional gate resistor, with an additional resistance R_{G,int}, that is spatially removed from the device active portions. For example, the gate structure may be disposed over the active cell areas and be located on either of the two opposing major surfaces of the die. Methods of forming such gate contact are also provided. Group III nitride-based HEMT dies designed with two gate pads may be utilized for a higher active area to chip size ratio with the proposed design. One gate resistor is provided for each gate pad. Such a two gate pad arrangement may be used to provide bi-directional switches.

The fabrication of a lateral GaN HEMT with the Source/Drain/Gate contacts on the opposing sides may be achieved by using Through-Silicon-Vias or Though-Substrate-Vias (TSVs). Such heterogeneous integration and advanced packaging provide increased functionality. This allows a direct routing of the Drain/Source/Gate signals vertically as opposed to routing to the periphery and wire bonding to an interposer or printed circuit boards. This vertical routing enables in shorter electrical path lengths, which enables reduced electrical parasitic such as resistive capacitive time delays. In addition to electrical improvements, the use of TSVs enables an increased number of inputs and outputs because they can be arranged throughout the area of the chip as opposed to utilizing only the perimeter of the chip. In an embodiment, a TSV process is used herein to route the Gate contact to the wafer back-side. This enables the chip front-side of a lateral GaN HEMT to be directly contacted to substrates in a flipped-chip approach using die-attach techniques. A source pad, which may be vertically routed through similar TSV concepts, may be located on the same chip side as the gate pad and the drain pad located on the opposite chip side to provide a vertical GaN HEMT architecture. A similar fabrication concept may be used in order to accommodate an additional gate resistor R_{G,int} remote to the 2-DEG and to form a gate pad on the opposite side of the 2-DEG from the gate fingers.

A method to fabricate the proposed chip designs comprises forming contact patterns that are aligned to an existing gate finger (node). A selective contact etch process may be used to etch & form via structures in the support substrate, Group III nitride material and/or electrically insulating layers, e.g. inter layer dielectrics. An insulating layer may be deposited on the etched sidewalls of the support substrate and Group III nitride, for example, using SiO₂, Si₃N₄, AlOₓ or any other dielectric material and then one or more metals are conformally deposited into the vias to form an electrically conductive via, i.e. a vertical through contact.

In an embodiment, the gate resistor is routed together with the source potential to the rear side of the device. The gate resistor is formed on or in the rear surface of the support substrate, e.g. silicon. Before the implementation of the TSV insulation for gate and source routing, trenches for the gate resistor are formed, e.g. etched, into the backside of the silicon substrate. These gate resistor trenches have a greater width than needed for the specific R_{g,int} requirement. During TSV insulation process, these gate resistor trenches are also lined with electrical insulation, for example, using the same process as that used to line the through substrate vias with electrically insulating material, thereby reducing the trench width to yield the desired gate resistance R_{g,int} and electrically isolating the gate potential form the substrate’s source potential. The electrically conductive material, e.g. one or more metal layer, is also deposited into the gate resistor trench and onto the rear side of the support substrate to form the gate and source pad. The additional gate resistor with a resistance R_{g,int} is integrated as an isolated entity within the support substrate of the Group III nitride device

Thus, Group III nitride transistor devices are provided in which it is possible to tune the gate resistance R_{G,int} for devices that are to be used in modules or packages where parallelization is important. This allows the gate resistance value to be tuned appropriately in order to damp any oscillations arising at high switching speeds or inter-chip oscillations. The size of the gate pad may also be tuned. This enables a higher flexibility to apply a diverse pool of so-called Back End interconnect technologies, e.g. wire boding, clips, etc., thus increasing freedom-of-design in Back End routing.

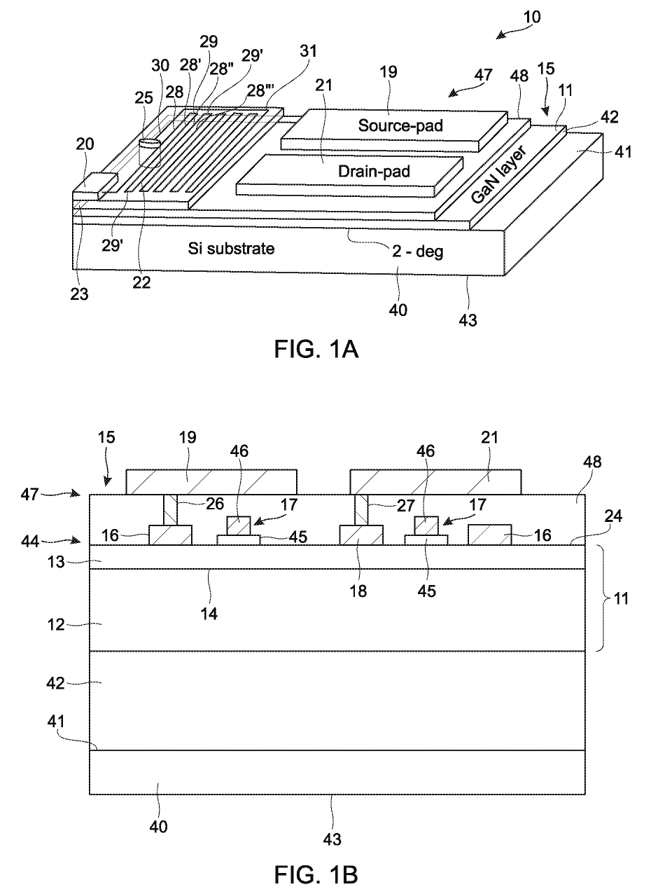

FIG. 1A illustrates a schematic perspective view and FIG. 1B illustrates a schematic cross-sectional view of a portion of a Group III nitride transistor device 10 according to an embodiment.

The Group III nitride transistor device 10 comprises a Group III nitride body 11 which comprises a Group III nitride channel layer 12 and a Group III nitride barrier layer 13, which is arranged on the Group III nitride channel layer 12 and forms a heterojunction 14 therebetween. The heterojunction 14 may be capable of supporting a two-dimensional charge gas, such as a two-dimensional electron gas (2DEG) or a two-dimensional hole gas (2DHG). The Group III nitride channel layer 12 has a different composition and a different bandgap from the Group III nitride barrier layer 13. In one embodiment, the Group III nitride channel layer 12 is formed of gallium nitride (GaN) and the Group III nitride barrier layer 13 is formed of aluminium gallium nitride, AlₓGa₍₁₋ₓ₎N, where 0 < x < 1. The Group III nitride body 11 comprises an active area 15 which contributes to load switching. The Group III nitride transistor device 10 may be a HEMT (High Electron Mobility Transistor).

The Group III nitride transistor device 10 further comprises a source finger 16, a gate finger 17 and a drain finger 18 which are arranged on the Group III nitride barrier layer 13. The source finger 16, the gate finger 17 and the drain finger 18 have an elongate stripe-like structure and extend substantially parallel to one another. The gate finger 17 is arranged laterally between the source finger 16 and the drain finger 18. This arrangement of the source finger 16, gate finger 17 and gate finger 18 may be called a transistor cell. The Group III nitride transistor device 10 further comprises a source pad 19 which is electrically coupled to the source finger 16, a gate pad 20 which is electrically coupled to the gate finger 17 and a drain pad 21 which is electrically coupled to the drain finger 18.

Commonly, the Group III nitride transistor device 10 comprises a plurality of transistor cells each comprising a source finger 16, a gate finger 17 and a drain finger 18. Neighbouring ones of the transistor cells may include a common drain finger 18 and/or common source finger 16 so that the fingers are arranged in a repeating pattern of source gate drain gate source gate drain on the Group III nitride barrier layer 13. The active area 15 corresponds to the area of the Group III nitride body 11 that is located directly under the transistor cells.

Each of the source fingers 16 may be connected to a common source pad 19, the drain fingers 18 to a common drain pad 21 and the gate fingers 18 to a common gate pad 20. It is, however, possible for the Group III nitride transistor device 10 to include more than one source pad 19 and/or more than one gate pad 20 and/or more than one drain pad 21. In these embodiments, a subsection of the total number of source fingers may be connected to each of the two or more source pads, a subsection of the total number of gate fingers is connected to each of the two or more gate pads and a subsection of the total number of drain fingers is connected to each of the two or more drain pads.

The gate finger 17 may comprise a p-doped Group III nitride finger 45 that is located on and is in direct contact with the Group III nitride barrier layer 13 and a gate metal finger 46 that is located on and in direct contact with the p-doped Group III nitride finger 45. The p-doped Group III nitride finger 17 may comprise GaN doped with Mg, for example. This arrangement of the gate finger 17 produces an enhancement mode device which is normally off. The gate finger 17 may, in addition to, or in place of, the p-doped Group III nitride finger 44 have a recessed structure to form an enhancement mode device which is normally off.

Typically, the Group III nitride body is cuboid 11 so that the first major surface 24 is square or rectangular. In this embodiment, the first major surface 24 is provided by the Group III nitride barrier layer 13. The gate pad 20 may be located in a corner of the first major surface 24 of the Group III nitride body 11. In other embodiments, the gate pad 20 may be located on the first major surface 24, intermediate the length of one side of the Group III nitride body 11. In embodiments including two gate pads, two gate pads may be located at two adjacent corners of the first major surface 24.

The Group III nitride transistor device 10 further comprises an additional gate resistor 22 which is electrically coupled between the gate pad 20 and the gate finger(s) 17 of the transistor device 10. The gate resistor 22 can be seen in the perspective view of FIG. 1A. The gate resistor 22 is located at least partially on and above the active area 15 of the semiconductor device 10.

In embodiments in which a plurality of gate fingers 17 are located on the Group III nitride barrier layer 13, these may be connected at one end by a gate runner, which cannot be seen in FIGS. 1A and 1B. The gate resistor 22 is connected between the gate runner and the gate pad 20 such that the gate resistor 22 provides an additional resistance in the electrical path between the common gate pad 20 and the gate runner.

Since the gate resistor 22 is located above the active area 15 of the transistor device 10, additional area on the Group III nitride body 11 is not required for solely supporting or forming the gate resistor 22. Therefore, the lateral size of the Group III nitride body 11 need not be increased to accommodate the gate resistor 22. In some embodiments, the gate resistor 22 may be fabricated from one or more of the electrically conductive layers of the metallisation structure formed on the front and/or back of the Group III nitride transistor device 11. Thus, the gate resistor 22 can be considered to be integrated into the metallization structure.

An electrically insulating layer 23 may be formed on the first major surface 24 of the Group III nitride body which covers the source finger 16, the gate finger 17 and the drain finger 18. The gate pad 20 and the gate resistor 22 are positioned on the insulating layer 23. In these embodiments, a gate via 25 extends from the gate finger 17, or typically the gate runner, through the insulating layer 23 to the gate resistor 22 located on the upper surface of the insulating layer 23. The gate pad 20 and the gate resistor 20 are located in a different lateral plane from the gate runner and the gate fingers 17. Optionally, the source pad 19 and the drain pad 21 are also be positioned on the insulating layer 23.

Referring to FIG. 1A, the gate resistor 22 extends between the gate via 25 and the gate pad 20. The gate resistor 22 has the form of a planar metal trace which has a meander or serpentine-type shape. This allows the gate resistor 22 to have a large resistance and be accommodated in a small area. It also allows the resistance of the gate resistor 22 to be adjusted or tuned, for example by changing the thickness and/or width of the trace or by adjusting the length of the metal trace. The serpentine shape comprises a plurality of elongate stripe-like sections 28 and connection sections 29, whereby a connection section extends between the elongate sections at alternate ends so as to form a continuous meandering form. The serpentine shape includes at least one loop, each loop comprising two substantially parallel elongate metal traces 28, 28’ having a first end and an opposing second end and a loop connection metal trace 29 which connects the first ends of the two substantially metal traces to form a U-shape. The loop connection traces 29 may extend substantially perpendicularly to the elongate metal traces 28. A second loop connection trace 29’ extends from the second end of one of the two elongate metal traces 28’ to the second end of a third elongate metal trace 28’’, a third lead connection metal trace 29’’ extends from the first end of the third elongate metal trace 28’’ to the first end of a fourth elongate metal trace 28’’’ and so on.

The transistor device 10 illustrated in FIGS. 1A and 1B enables independent tuning of the gate resistor 22 and its resistance, R_{G,int}. This is useful for Group III nitride devices that are accommodated in modules or packages where parallelization is important. The value of R_{G,int} of the gate resistor 22 can be appropriately tailored, e.g. by changing the dimensions, e.g. length, of the planar metal trace providing the gate resistor 22 in order to damp oscillations arising due to high switching speed or inter-chip oscillations. An increased freedom-of-design to structure the gate pad dimensions is also provided which provides higher flexibility for interconnect parameters, e.g. wire bond settings/design rules, to be optimized.

The electrically insulating layer 23, on which the gate resistor 22 and gate pad 20 are formed, allows a larger template for the gate resistor 22 to be structured. A greater freedom of design is provided which allows the gate resistor to be adapted to the needs of a specific application.

In an embodiment, the planar metal trace of the gate resistor 22 comprises an outermost loop comprising an elongate trace 30 extending from the gate via 25 and parallel to the first elongate trace 28 of the first loop and a transverse section 31. The transverse section 31 extends from the elongate trace 30 adjacent the first distal ends of the metal traces 28 and parallel to the transverse loop connection sections 29. The transverse section 31 then extends into the outermost elongate metal trace 28 of the serpentine shape located at the opposite side from the first elongate trace 28. The first metal trace 28 of the first loop, which is located adjacent the elongate metal trace 30 extending from the gate via 25, extends into the gate pad 20. Thus, the gate pad 20 and the gate via 25 are connected to opposing ends of the planar trace 22 and are located adjacent one another at one side of the gate resistor 22 and insulating layer 23. The arrangement of the outermost loop with its elongate trace 30 and transverse section 31 which surround two sides of the loops of the serpentine structure enables the cancellation of magnetic field generated from current flowing the metal trace.

The insulation layer 23 may comprise two or more sublayers, for example a first sublayer which is in direct contact with the upper surface 24 of the Group III nitride barrier layer 13 and a second sublayer which is positioned on the first sublayer. The first sublayer may the comprise an oxide, for example silicon oxide and the first sublayer may comprise a nitride, for example silicon nitride.

In some embodiments, the source pad 19 is electrically connected to the source fingers 16 by an electrically conductive redistribution structure that includes at least one conductive via 26 which extends through a second electrically insulating layer 48 and the drain pad 21 is electrically coupled to the drain finger 18 by at least one conductive via 27 extends through the second electrically insulating layer 48. The second electrically insulating layer 48 may extend over the entire first major surface 24 and the first electrically insulating layer 23 is located on a portion of the second electrically insulating layer adjacent the source pad 19 and drain pd 21.

Referring to the cross-sectional view of FIG. 1B, in some embodiments, the Group III nitride body 11 is formed on a support substrate 40 which has a first major surface 41 which is capable of supporting the growth of at least one epitaxial Group III nitride layer. The support substrate 40 may be formed of a foreign substrate, that is formed of a material other than a Group III nitride. The support substrate 40 may be formed of a single crystal silicon wafer or a monocrystalline silicon layer and may have a <111> or <110> orientation. Alternatively, the support substrate 40 may be formed of silicon carbide or sapphire. A buffer layer 42 may be formed between the support substrate 40 and the Group III nitride body 11 and therefore extend between the growth surface 41 of the support substrate 40 and the Group III nitride channel layer 12. The support substrate 40 has a second major surface 43 which opposes the growth surface 41 and which provides the rear second major surface of the Group III nitride device 10.

In some non-illustrated embodiments, the buffer structure 42 may further include a back barrier layer. The Group III nitride channel layer 12 is formed on the back barrier layer and forms a heterojunction with the back barrier layer and the Group III nitride barrier layer 13 is formed on the Group III nitride channel layer 12. The back barrier layer has a different bandgap to the channel layer 12 and may comprise AlGaN, for example, if the Group III channel layer 12 comprises GaN. The composition of the AlGaN of the back barrier layer may differ from the composition of the AlGaN used for the barrier layer 13.

A typical transition or buffer structure for the buffer layer 42 that is suitable for a silicon substrate 40 includes a AlN starting layer, which may have a thickness of several 100nm, on the silicon substrate 40 followed by a AlₓGa₍₁₋ₓ₎N layer sequence, the thickness again being several 100nm´s for each layer, whereby the Al content of about 50-75% is decreased down to 10-25% before the Group III nitride channel layer 12, e.g. GaN layer, or AlGaN back barrier, if present, is grown. Alternatively, a superlattice buffer can be used. Again, an AlN starting layer on the silicon substrate is used. Depending on the chosen superlattice, a sequence of AlN and AlₓGa₍₁₋ₓ₎N pairs is grown, where the thickness of the AlN layer and AlₓGa₍₁₋ₓ₎N is in the range of 2-25nm. Depending on the desired breakdown voltage the superlattice may include between 20 and 100 pairs. Alternatively, an AlₓGa₍₁₋ₓ₎N layer sequence as described above can be used in combination with the above mentioned superlattice.

In the embodiment illustrated in FIGS. 1A and 1B, all of the contact pads 19, 20, 21, which serve as external contact areas for electrically connecting the Group III nitride transistor device 10 to a further device or a redistribution board, and the gate resistor 22 are formed on the same side, namely the front side 44 of the Group III nitride transistor device 10. The front side 44 is positioned above the Group III nitride body 11. The rear side of the Group III nitride transistor device 10 is provided by the rear side 43 of the support substrate 40 and opposes the front side 44.

In some embodiments, the front side metallization 47 that is located on the front side 44 of the Group III nitride transistor device 10 provides the source pad 19, gate pad 20, drain pad 21, the gate resistor 22 and the electrically conductive redistribution structure from the source fingers 16 to the source pad 19, from the gate fingers 17 by way of the gate via 25 and gate resistor 22 to the gate pad 20 and from the drain fingers 18 to the drain pad 21. The gate resistor 22 can be considered to be integrated into the front side metallization 47. The gate resistor 22 is also located at least partially above the active area 15 of the Group III nitride device 10 that contributes to load switching. The active area of the Group III nitride transistor device 10 is located under the transistor cells and under the source fingers 16, gate fingers 17 and drain fingers 18. At least a part of the gate resistor is, therefore, located above and overlaps at least a part of one or more transistor cells and is located above and overlaps at least part of one source finger 16, one gate finger 17 and one drain finger 18 that form a transistor cell. The gate resistor 22 is electrically insulated from the underlying source finger 16 and drain finger 18 by the first electrically insulating layer 23 and the second electrically insulating layer 48, if present.

FIGS. 1A and 1B illustrate one example of a frontside metallisation structure 47 comprising the additional gate resistor 22 between the gate fingers 17 and the gate pad 20 and also separate redistribution structures from the source fingers 16 and the drain fingers 18 to their respective pad 19, 21. The front side metallisation structure 47 and the redistribution structures provided by the front side metallisation structure 47 is, however, not limited to this arrangement and may have other structures.

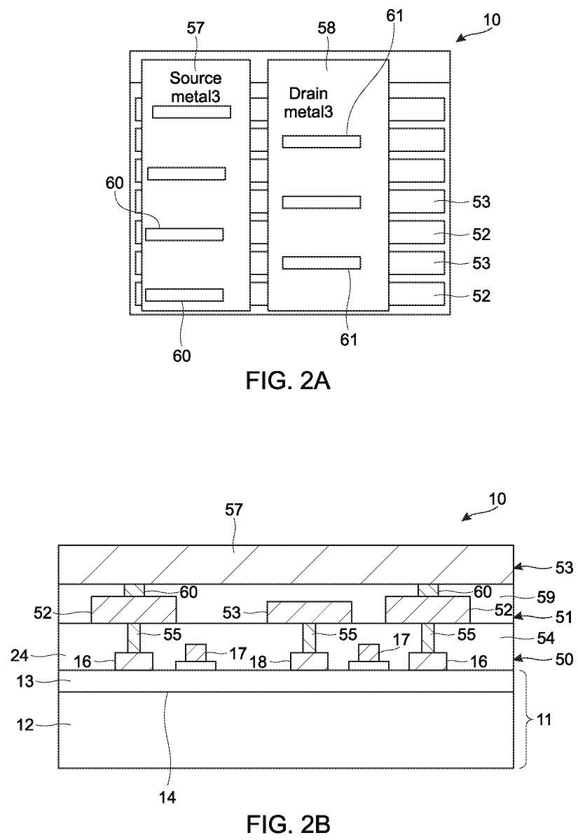

FIG. 2A illustrates a schematic top view and FIG. 2B illustrates a cross-sectional view of a frontside metallisation structure 47 of a Group III nitride transistor device 10 according to an embodiment. The frontside metallisation structure 47 has three electrically conductive layers. The lowermost electrically conductive first layer 50 is in direct contact with the first major surface 24 of the Group III nitride body 11 and with the Group III nitride barrier layer 13 and is structured to form the source fingers 16, the gate fingers 17 and the drain fingers 18. An electrically insulating layer 54 is positioned on the first major surface 24 so as to cover the source fingers 16, the gate fingers 17 and drain fingers 18. A second electrically conductive layer 51 comprises elongate source sections 52, one of which is aligned with and positioned on each of the source fingers 17, and elongate drain sections 53, one of which is aligned with and positioned on each of the drain fingers 18. The electrically insulating layer 54 has openings 55 into which the source and drain sections 53, 54 extend so as to electrically connect the individual source sections 53 with their respective underlying source finger 16 and the individual drain sections 54 with their respective underlying drain finger 18.

A further electrically insulating layer 59 is located on the second metallisation layer 51 and a the third electrically conductive layer 56 is located on the further insulating layer 59. The third electrically conductive layer 56 comprises at least one source bus 57 and at least one drain bus 58. The source bus 57 extends over and substantially perpendicularly to the source sections 53 and drain sections 54. The source bus 57 is electrically connected to the source sections 53 by way of electrically conductive vias 60 that extend through the electrically insulating layer 59. The source bus 57 is electrically insulated from the underlying drain sections 54 by the electrically insulating layer 59. The conductive vias 60 are located in a row under the source bus 57. The drain bus 58 extends over and substantially perpendicularly to the source sections 53 and the drain sections 54 and parallel to the source bus 57. The drain bus is electrically connected to the underlying drain sections 54 by electrically conductive vias 61 that extend through the electrically insulating layer 59. The drain bus 58 is electrically insulated from the underlying source sections 53 by the electrically insulating layer 59. The conductive vias 61 are located in a row under the drain bus 58.

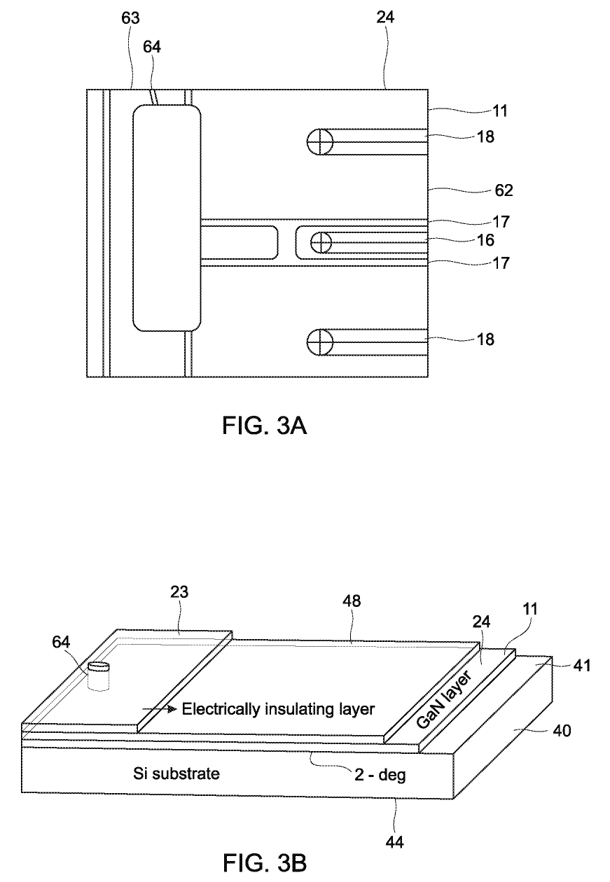

FIGS. 3A-3C illustrate a method for fabricating a Group III nitride transistor device and may be used to fabricate the Group III nitride transistor device 10 illustrated in FIGS. 1A and 1B. FIG. 3A shows a top view of a portion of the first major surface 24 of a Group III nitride body 11. At least one transistor cell including a source finger 16, a gate finger 17 and a drain finger 18 is located on the first major surface 24.

In arrangements of two or more transistor cells, in which gate fingers 17 are located on opposing sides of a common source finger 16, these gate fingers 17 may be electrically connected to one another by a gate connection portion 62, which can be seen in the top view of FIG. 3A. The gate connection portion 62 extends substantially perpendicularly to the length of the gate fingers 17 and is spaced apart from distal end of the source finger 18. The gate fingers 17 extend beyond the gate connection portion 62 and beyond the distal end of the source fingers 16 and drain fingers 18 to a gate runner 63 which extends substantially perpendicularly to the length of the gate fingers 17 and which electrically connects the gate fingers 17 to one another.

Referring to FIG. 3B, a second electrically insulating layer 48 is located on the first major surface 24 of the Group III nitride layer 13. The first electrically insulating layer 23 is formed on the second electrically insulating layer 48 and has a lateral area which is less than the lateral area of the underlying second electrically insulating layer 48. The lateral area of the first electrically insulating layer 23 corresponds to the overall area required for the gate resistor 22. The first electrically insulating layer 23 covers at least end portions of the gate fingers 17, the gate runner 63 and end portions of the source and drain fingers 16, 18. In order to form the electrical connection between the gate runner 63, which is located in the lowermost conductive layer 50 of the frontside metallisation 47 and the gate resistor 22 which is to be formed on the opposing upper surface of the insulating layer 23, a via hole 64 is formed through the first and second electrically insulating layers 23, 48 which exposes a portion of the gate runner 63. In some embodiments, a further electrically insulating layer may be formed on the side wall of the via hole 64. Electrically conductive material, for example a metal such as copper, is deposited onto at least the sidewalls of the via hole 64 and may even fill the via hole 64 so as to form the electrically conductive via 25 which extends through the thickness of the first and second electrically insulating layers 23, 48.

Referring to FIG. 3C, the gate resistor 22 may be formed by depositing a metallic layer onto the electrically insulating layer 23 and structuring this metal layer so as to form a meandering metallic trace comprising a plurality of open-ended loops connected in series. One end of the metallic trace is electrically connected to the electrically conductive via 25 and the other end of the metallic trace is electrically connected to the gate pad 20. Alternatively, the metallic trace of the gate resistor 22 may be selectively deposited onto the electrically insulating layer.

The gate pad 20, the source pad 19 and the drain pad 21 may also be fabricated from the conductive layer used to form the gate resistor 22. Alternatively, the source pad 19, the gate pad 20 and the drain pad 21 may be fabricated in a different conductive layer to the planar trace of the gate resistor 20. Alternatively, the conductive layer used to form the gate resistor 22 may form a lower sublayer of the gate pad 20, the source pad 19 and the drain pad 21 and the thickness of these pads 19, 20, 21 may be increased by depositing a second sublayer onto the first sublayer.

The source pad 19 may provide the source bus 57 which electrically connects the source fingers 16 in parallel. The drain pad 21 may provide the drain bus 58 which electrically connects the drain fingers 18 in parallel. The gate resistor 22 is formed in the front side metallisation 47 of the Group III nitride transistor 10 and is at least partially located above the active region 15 of the Group III nitride transistor device 10. The gate resistor 22 and the gate pad 20 are formed on the electrically insulating layer 23, whereas the source pad 19 and the drain pad 21 are located on the lower second electrically insulating layer 48 and laterally adjacent and spaced apart from the electrically insulating layer 23.In the embodiment illustrated in FIGS. 1A-1B and 3A-3C, the gate resistor 22 and the gate pad 20 are located in a different plane to the plane of the source pad 19 and drain pad 21, since the electrically insulating layer 23 is located on a portion of the first major surface 24 only.

In some embodiments of the Group III nitride transistor device 10, the source pad 19, the gate pad 20, the drain pad 21 and the gate resistor 22 are located on the same side of the device 10. In the embodiments of the Group III nitride transistor illustrated in and described with reference to FIGS. 1A-3C, the source pad 19, the gate pad 20, the drain pad 21 and the gate resistor 22 are located on the front side 44 and are integrated into the front side metallization 47. In other embodiments, the source pad 19 and the drain pad 20 are located on opposing sides of the Group III nitride device. 10. In an embodiment, the drain pad 21 is located on the front side 44 and the source pad 19, the gate pad 20 and the gate resistor 22 are located on the rear side 43 of the device 10. In an alternative embodiment, the drain pad 21 is located on the rear side 43 and the source pad 19, the gate pad 20 and the gate resistor 22 are located on the front side 44 of the device 10. The gate pad 20 and the gate resistor 22 may alternatively be located on the same side as the drain pad 21.

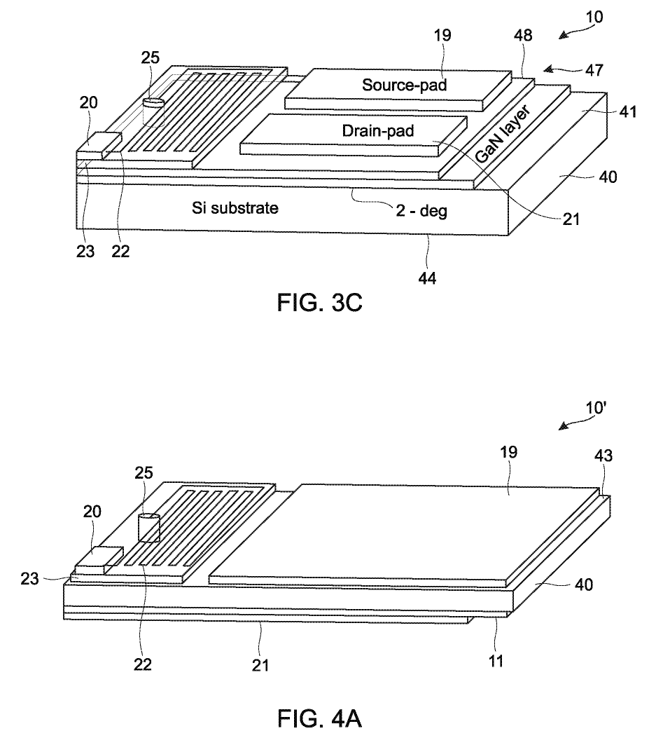

FIGS. 4A and 4B illustrate an example of Group III nitride transistor device 10’ according to another embodiment. FIG. 4A illustrates a schematic perspective view and FIG. 4B illustrates a schematic cross-sectional view of the Group III nitride transistor device 10’. The Group III nitride transistor device 10’ differs from that illustrated in FIGS. 1A-3C in that the source pad 19, the gate pad 20 and the gate resistor 22 are located on the opposing rear surface 43 of the support substrate 40 and the drain pad 22 is located on the opposing front side 44. The drain pad 21 may be integrated in the frontside metallisation 47. The source pad 19, the gate pad 20 and the gate resistor 22 are integrated into the rear side metallization. The gate resistor 22 that is located on the rear side 43 may have a similar structure to that illustrated in FIGS. 1A and 1B.

The drain pad 21 may extend over substantially all of the first major surface 24 of the Group III nitride body 11. The source pad 19 is positioned on the second major surface 43 of the silicon substrate is electrically connected to the source fingers 16 located on the opposing first major surface 24 of the ‘Group III nitride body 11 by at least one electrically conductive via 70 which extends through the thickness of the silicon substrate 40, through the Group III nitride-based buffer layer 42 and also through the Group III nitride body 11 to the first major surface 24 of the Group III nitride body 11. The source pad 19 may be electrically connected to the source fingers 17 or a source bus that is connected to the source fingers 17 by one or a plurality of the conductive vias 70. The gate pad 20 is located adjacent the source pad 19 on the second major surface 43 of the support substrate 40 and is electrically connected to the gate fingers 18 on the opposing first side 24 of the device 10’ by at least one conductive via 71 which extends from the second major surface 43, through the silicon substrate 40, through the buffer layer 42 and through the Group III nitride body 11 to the first major surface 24. The gate via 71 may be arranged under, and in contact with, the gate runner 63, for example, and electrically connects the gate runner 63 and therefore the gate fingers 18 on the front side 24 of the Group III nitride body 11 to the gate resistor 22 and the gate pad 20 arranged on the opposing surface 43 of the Group III nitride device 10.

The Group III nitride transistor device 10’ illustrated in FIGS. 4A and 4B has a quasi-vertical arrangement since the source and drain pads 19, 21 are arranged on opposing surfaces 24, 43 of the device 10’. In some embodiments, such as that illustrated in FIGS. 4A and 4B, the drain pad 21 is mounted to a redistribution board 72, for example by solder. This arrangement may be referred to as drain down. This arrangement may be used to provide an improved thermal path for heat dissipation. In some embodiments, the drain pad 21 may comprise a plurality of bumps 73 which may be connected to a pad 74 located on the upper surface 75 of redistribution board 72 by solder, for example. The bumps 73 may comprise solder. Alternatively, the source and gate pads 19, 20 may be mounted on the redistribution board 72 in a source down arrangement.

In the embodiment illustrated in FIGS. 4A and 4B, the gate resistor 22 is located on a planar electrically insulating layer 23 that is located on the planar rear surface 43 of the support substrate 40. The gate resistor 22 has the form of a planar trace which is positioned on the planar electrically insulating layer 23 and may have a form as described with reference to FIGS. 1A and 1B. The gate resistor 22 is electrically connected at one end to the gate runner 63 on the frontside 24 by the conductive via 71 which extends through the thickness of the support substrate 40 as well as the Group III nitride body 11. The gate resistor 22 is electrically connected at its opposing end to the gate pad 20. For example, the opposing end of the gate resistor 22 may be integral with the gate pad 20. However, the gate resistor 22 is not limited to this arrangement and may have other forms.

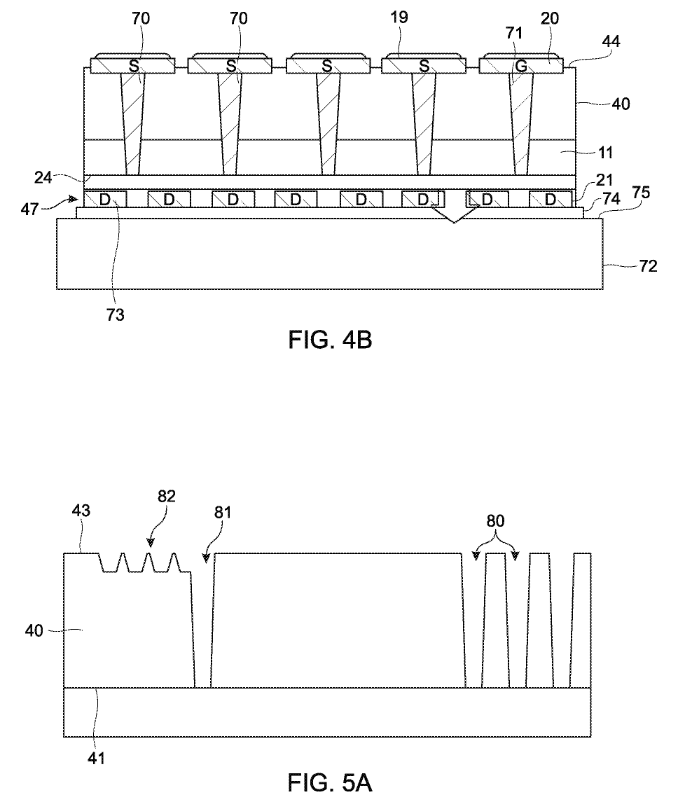

FIGS. 5A-5D illustrate a method for fabricating a gate resistor 22 which is located in a groove 82 formed in the second major surface 43 of the support substrate 40. The groove 82 may also be described as a trench. At this stage, the buffer layer 42 and the Group III nitride body 11 including the Group III nitride channel layer 12 and Group III nitride barrier layer 13 have been epitaxially grown on the growth surface 41 of the support substrate 40 and the source fingers 16, drain fingers 17, gate fingers 18 and gate runner 63 formed on the first major surface 24 of the Group III nitride barrier layer 13.

Referring to FIG. 5A, a first through via 81 is formed which extends from the second major surface 43 of the support substrate 40 through the thickness of the support substrate 40 and through the thickness of the Group III nitride body 11. The through via 81 may be positioned under and expose a portion of the gate runner 63 located on the first major surface 24 of the Group III nitride body 11. One or more through second through vias 80 for forming a connection to the source fingers 16 are also formed. For example, the one or more second through vias 80 may be positioned above a source bus located on the first major surface 24 of the Group III nitride body 11. Additionally, a groove 82 is formed in the second major surface 43 of the support substrate 40 and has a lateral shape suitable for forming the gate resistor. For example, the groove 82 may have a serpentine form comprising a plurality of loops corresponding to the shape of the gate resistor shown in FIGS. 1A and 1B. One end of the groove 82 extends into the through-hole 81 for the gate. The groove 82 and the through holes 80, 81 may be formed by methods such as etching, laser ablation, etc. The groove 82 may have larger dimensions than those required by the gate resistor so as to provide the desired gate resistance in order to allow for the volume of the groove 82 that is occupied by the electrical insulation provided between the electrically conductive material of the gate resistor and the support substrate 40.

Referring to FIG. 5B, an electrically insulating layer 83 is then formed which lines the through-holes 80, 81 and also lines the groove 82. The electrically insulating layer 83 may initially further cover the second major surface 43 and be subsequently removed from the planar second major surface 43, for example by chemical mechanical polishing, such that it is located on the sidewalls of the through openings 80, 81 and the sidewalls and base of the groove 82 only. The electrically insulating layer 83 surrounds a gap in the through openings 80, 81 and surrounds a recess in the groove 82.

Referring to FIG. 5C, conductive material, for example a metal such as copper, is then inserted into the through-holes 80, 81 and into the groove 82 and may fill the through holes 80, 81 to form conductive vias 70, 71 and may also fill the groove 82. Afterwards, any electrically conductive material located on the second major surface 43 may be removed, for example by chemical mechanical polishing, so that the gate resistor 22 is formed by the conductive material remaining in the groove 82 and has a serpentine form.

Referring to FIG. 5D, the source pad 19 is deposited onto the second major surface 43 such that it is in contact with the conductive material in the conductive via 71 and gate pad 20 is deposited on the second major surface 43 which is in contact with a first distal end of the conductive material formed in the groove 82 which provides the gate resistor 22. The conductive material in the opposing second distal end of the groove 82 is integral with the conductive material in the of the gate via 71 and therefore electrically connects the gate resistor 22 to the gate through via 71 and the gate runner 63 and gate fingers 18 on the opposing first major surface 24 of the Group III nitride body 11.

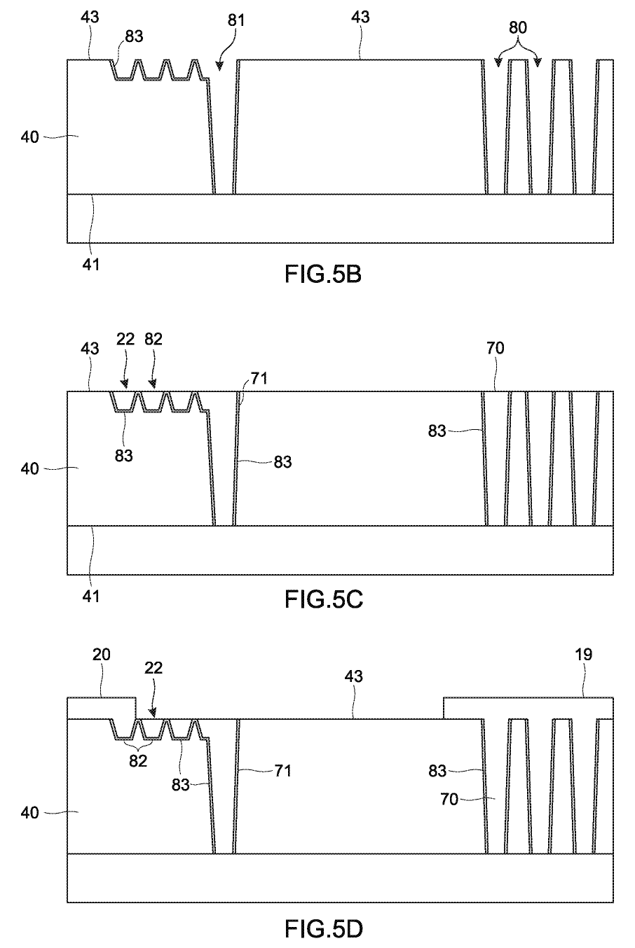

FIG. 6 Illustrates a Group III nitride transistor device 10’’ according to an embodiment in which the gate pad 19 and the drain pad 21 are formed in the frontside metallisation 47 and the source pad 20 is located on the opposing second side 33 of the support substrate 40 in the rear side metallisation. The device 10’’ may be mounted onto a redistribution board 72 by attaching the source pad 20 to a die pad 74, which is located on the first major surface 75 of the redistribution board 72, for example using solder. The source fingers 17 located on the first major surface 24 of the Group III nitride body 11 are connected to the source pad 20, which is located on the lower surface 43 of the support substrate 40, by way of one or more electrically conductive vias 70 which extend from the first major surface 24, which is formed by the Group III nitride barrier layer 13, to the opposing lower surface 43 of the support substrate 40. For example, one or more vias 70 may extend between a source bus, which is located on the first major surface 24, and the second major surface 43. The drain fingers 19, which are located on the first major surface 24, may be electrically connected together by a drain bus, which is located on the first major surface and which extends over and is electrically insulated from the intervening ones of the source fingers 16 and the gate fingers 18. The gate fingers 18, which are located on the first major surface 24, are electrically connected to the gate pad 20, which is also located on the first major surface, by, for example, a gate runner and the gate resistor 22, which cannot be seen in the cross-sectional view of FIG. 6. The gate resistor is also located on the first major surface 24.

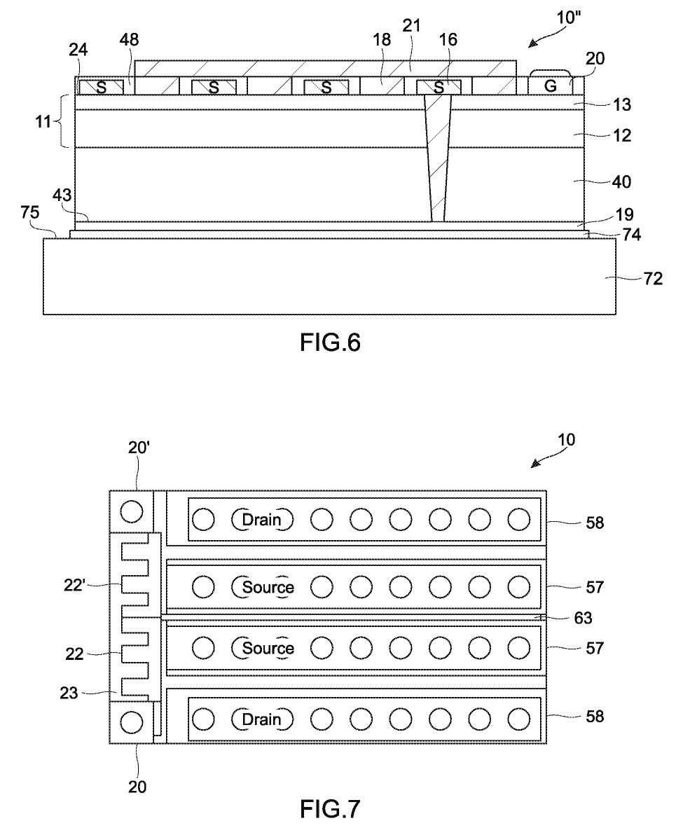

FIG. 7 Illustrates a top view of a Group III nitride device 10’’’ according to an embodiment. The Group III nitride device 10’’’ comprises two gate pads 20, 20’ that are electrically coupled to the gate runner 63 by a separate respective gate resistor 22, 22’. The gate gates 20, 20’ are arranged in adjacent corners of the first major surface 24. The two gate resistors 22, 22’ are arranged at least partially above the active area 15 of the Group III nitride device 10’’’. Each of the gate resistors 22, 22’ has the form of a planar trace formed on an electrically insulating layer 23. The planar trace may comprise copper and may have a meander form. The Group III nitride device 10’’’ may be configured as a bidirectional switch or as a transistor device. The elongate gate runner 63 which is connected to the gate fingers 17 extends along the centre of the first major surface 24 and an elongate source bus 57, which provides a source pad, extends parallel to the gate runner 63 adjacent the opposing sides of the gate runner 63. An elongate drain bus 58, which provides the drain pad 21, is arranged adjacent each of the source buses 57 and extends parallel to the source buses 57. One bump is located on each of the gate pads 20, 20; and a plurality of bumps are located on each of the source buses 57 and drain buses 58. The bumps may comprise solder, e.g. soft solder or a diffusion solder, or copper, for example. The resistance of the two gate resistors 22, 22’ may be adjusted individually and independently from the other, if desired, by for example changing he dimensions of the planar trace.

To summarise, a gate contact structure including the gate pad 20 and an additional gate resistor 22 which has an additional resistance, R_{G,int}, and which is spatially removed from the device active portions is provided. For example, the gate resistor 22 may be disposed over the active cell areas and be located on either of the two opposing major surfaces of the die.

As such, the inherent design limitation of space competing HEMT device and gate resistor 22 is mitigated. Greater portions of the active area 15 with its 2-DEG can be occupied by HEMT structures. This may be used to provide a reduced chip R_{DS,on} , while retaining the same die size, or to realize a chip shrink for a given R_{DS,on}.

Although the present disclosure is not so limited, the following numbered examples demonstrate one or more aspects of the disclosure.

Example 1. A Group III nitride transistor device, comprising: a Group III nitride body comprising an active area that contributes to load switching, a Group III nitride channel layer and a Group III nitride barrier layer that is arranged on the Group III nitride channel layer and forms a heterojunction therebetween; a source finger, a gate finger and a drain finger arranged on the Group III nitride barrier layer; a source pad electrically coupled to the source finger, a gate pad electrically coupled to the gate finger and a drain pad electrically coupled to the drain finger; a gate resistor electrically coupled between the gate pad and gate finger of the transistor device, wherein the gate resistor is located at least partially on the active area of the transistor device.

Example 2. The Group III nitride transistor device according to example 1, wherein the gate finger is arranged laterally between the source finger and the drain finger and the gate finger, source finger and drain finger extend substantially parallel to one another.

Example 3. The Group III nitride transistor device according to example 1 or example 2, further comprising a further gate pad and a further gate resistor that is electrically coupled between the further gate pad and the gate finger, wherein the further gate resistor is located at least partially on the active area of the transistor device.

Example 4. The Group III nitride transistor device according to any one of examples 1 to 3, wherein a plurality of source fingers, a plurality of gate fingers and a plurality of drain fingers are provided and the gate fingers are electrically connected to one another by a gate runner, wherein the gate resistor is electrically coupled between the gate runner and the gate pad.

Example 5. The Group III nitride transistor device according to any one of examples 1 to 4, wherein the gate resistor comprises a planar metal trace.

Example 6. The Group III nitride transistor device according to example 5, wherein the metal trace comprises at least one loop, the loop comprising two substantially parallel elongate metal traces having a first end and a loop connection metal trace that connects the first ends of the two substantially parallel metal traces.

Example 7. The Group III nitride transistor device according to example 6, further comprising an intermediate connection trace that extends from a second end of one of the two substantially parallel elongate traces, the second end opposing the first end, wherein the intermediate connection trace extends substantially parallel to the one of the two substantially parallel elongate traces and the loop connection metal trace of the loop to a gate via.

Example 8. The Group III nitride transistor device according any one of examples 1 to 7, wherein the gate resistor is arranged above, and spaced apart from, at least a portion of the source finger, the gate finger and the drain finger.

Example 9. The Group III nitride transistor device according to example 8, wherein an electrically insulating layer is arranged on at least a portion of the source finger, the gate finger and the drain finger and on the Group III nitride barrier layer and the gate resistor is arranged on the electrically insulating layer.

Example 10. The Group III nitride transistor device according to any one of examples 7 to 9, wherein the gate via extends through the electrically insulating layer and between the gate runner and the metal trace of the gate resistor.

Example 11. The Group III nitride transistor device according to example 9 or example 10, wherein the gate pad is located on the electrically insulating layer.

Example 12. The Group III nitride transistor device according to any one of examples 1 to 11, wherein the source pad, gate pad and drain pad are located laterally adjacent one another on the Group III nitride barrier layer.

Example 13. The Group III nitride transistor device according to any one of examples 1 to 12, further comprising a support substrate comprising a first major surface that is capable of supporting the epitaxial growth of at least one Group III nitride layer and a second major surface opposing the first major surface, wherein the Group III nitride channel layer is arranged on the first major surface of the support substrate and the gate resistor is arranged on and is electrically insulated from the second major surface of the support substrate.

Example 14. The Group III nitride transistor device according to example 13, wherein the support substrate comprises a material other than a Group III nitride.

Example 15. The Group III nitride transistor device according to any one of examples 1 to 14, wherein the metal trace forms part of the metallization structure on the Group III nitride barrier layer or on the second major surface of the support substrate.

Example 16. The Group III nitride transistor device according to any one of examples 13 to 15, wherein the gate resistor is formed in a groove formed in the second major surface of the support substrate.

Example 17. The Group III nitride transistor device according to example 16, wherein the groove has a meander form.

Example 18. The Group III nitride transistor device according to example 16 or example 17, wherein the groove is lined with an electrically insulating liner layer and a metal trace is located on the electrically insulating liner layer in the groove and forms the gate resistor.

Example 19. The Group III nitride transistor device according to example 18, wherein the gate resistor is electrically insulated from the second major surface of the support substrate by a further electrically insulating layer that is arranged on the second major surface of the support substrate and the gate resistor has the form of a planar metal trace that is located on the further electrically insulating layer.

Example 20. The Group III nitride transistor device according to any one of examples 13 to 19, wherein the gate resistor is electrically coupled to the gate finger by at least one electrically conductive via that extends from the second major surface of the support substrate through the support substrate, through the Group III nitride body to a gate runner that is located on the Group III nitride barrier layer.

Example 21. The Group III nitride transistor device according to any one of examples 1 to 20, wherein the source pad and the gate pad are located on the second major surface of the support substrate and the drain pad is located on the Group III nitride barrier layer.

Example 22. The Group III nitride transistor device according to example 21, further comprising one or more electrically conductive vias that extend between the source pad located on the second major surface of the support substrate and a source bus located on the Group III nitride barrier layer.

Example 23. The Group III nitride transistor device according to any one of examples 1 to 7, wherein the drain pad and the gate pad are located on the Group III nitride barrier layer and the source pad is located on the second major surface of the support substrate.

Example 24. The Group III nitride transistor device according to example 23, further comprising one or more electrically conductive vias extending between a source pad located on the second major surface of the support substrate and a source bus located on the Group III nitride barrier layer.

Example 25. The Group III nitride transistor device according to any one of examples 1 to 24, wherein the Group III nitride layer further comprises a Group III nitride buffer structure that is arranged on the first major surface of the support substrate, and the Group III nitride channel layer is arranged on the Group III nitride buffer structure.

Example 26. The Group III nitride transistor device according to any one of examples 1 to 25, wherein the Group III nitride transistor device is a HEMT.

Example 27. The Group III nitride transistor device according to any one of examples 1 to 26, wherein the electrically insulating layer is formed of an oxide or a nitride.

Example 28. The Group III nitride transistor device according to any one of examples 1 to 27, wherein the electrically insulating layer is formed of silicon dioxide.

Example 29. The Group III nitride transistor device according to any one of examples 1 to 28, wherein the support substrate is formed of a monocrystalline silicon substrate.2.

Example 30. The Group III nitride transistor device according to example 29, wherein the first major surface of the monocrystalline silicon substrate has a <111> orientation.

Spatially relative terms such as "under", "below", "lower", "over", "upper" and the like are used for ease of description to explain the positioning of one element relative to a second element. These terms are intended to encompass different orientations of the device in addition to different orientations than those depicted in the figures. Further, terms such as "first", "second", and the like, are also used to describe various elements, regions, sections, etc. and are also not intended to be limiting. Like terms refer to like elements throughout the description.

As used herein, the terms "having", "containing", "including", "comprising" and the like are open ended terms that indicate the presence of stated elements or features, but do not preclude additional elements or features. The articles "a", "an" and "the" are intended to include the plural as well as the singular, unless the context clearly indicates otherwise. It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A Group III nitride transistor device, comprising:
a Group III nitride body comprising an active area that contributes to load switching, a Group III nitride channel layer and a Group III nitride barrier layer that is arranged on the Group III nitride channel layer and forms a heterojunction therebetween;
a source finger, a gate finger and a drain finger arranged on the Group III nitride barrier layer;
a source pad electrically coupled to the source finger;
a gate pad electrically coupled to the gate finger;
a drain pad electrically coupled to the drain finger; and
a gate resistor electrically coupled between the gate pad and the gate finger,
wherein the gate resistor is located at least partially on the active area of the transistor device.

2. The Group III nitride transistor device of claim 1, wherein a plurality of source fingers, a plurality of gate fingers and a plurality of drain fingers are provided and the gate fingers are electrically connected to one another by a gate runner, and wherein the gate resistor is electrically coupled between the gate runner and the gate pad.

3. The Group III nitride transistor device of claim 1, wherein the gate resistor comprises a planar metal trace.

4. The Group III nitride transistor device of claim 3, wherein the metal trace comprises at least one loop comprising two substantially parallel elongate metal traces having a first end and a loop connection metal trace that connects the first ends of the two substantially parallel metal traces.

5. The Group III nitride transistor device of claim 4, further comprising:
an intermediate connection trace that extends from a second end of one of the two substantially parallel elongate traces, the second end opposing the first end,
wherein the intermediate connection trace extends substantially parallel to the one of the two substantially parallel elongate traces and the loop connection metal trace of the loop, to a gate via.

6. The Group III nitride transistor device of claim 5, wherein the gate via extends through the electrically insulating layer and between the gate runner and the metal trace of the gate resistor.

7. The Group III nitride transistor device of claim 1, wherein the gate resistor is arranged above, and spaced apart from, at least a portion of the source finger, the gate finger and the drain finger.

8. The Group III nitride transistor device of claim 7, wherein an electrically insulating layer is arranged on at least a portion of the source finger, the gate finger and the drain finger, and on the Group III nitride barrier layer, and wherein the gate resistor is arranged on the electrically insulating layer.

9. The Group III nitride transistor device of claim 8, wherein the gate pad is located on the electrically insulating layer.

10. The Group III nitride transistor device of claim 1, wherein the source pad, the gate pad and the drain pad are located laterally adjacent one another on the Group III nitride barrier layer.

11. The Group III nitride transistor device of claim 1, further comprising:
a support substrate comprising a first major surface that is capable of supporting epitaxial growth of at least one Group III nitride layer and a second major surface opposing the first major surface,
wherein the Group III nitride channel layer is arranged on the first major surface of the support substrate and the gate resistor is arranged on and is electrically insulated from the second major surface of the support substrate.

12. The Group III nitride transistor device of claim 11, wherein the gate resistor is formed in a groove formed in the second major surface of the support substrate.

13. The Group III nitride transistor device of claim 12, wherein the groove has a meander form.

14. The Group III nitride transistor device of claim 12, wherein the groove is lined with an electrically insulating liner layer, and wherein a metal layer is located on the electrically insulating liner layer in the groove and forms the gate resistor.

15. The Group III nitride transistor device of claim 11, wherein the gate resistor is electrically insulated from the second major surface of the support substrate by a planar electrically insulating layer that is arranged on the second major surface of the support substrate, and wherein the gate resistor has a form of a planar metal trace that is located on the planar electrically insulating layer.

16. The Group III nitride transistor device of claim 11, wherein the gate resistor is electrically coupled to the gate finger by at least one electrically conductive via that extends from the second major surface of the support substrate through the support substrate and the Group III nitride body to a gate runner that is located on the Group III nitride barrier layer.

17. The Group III nitride transistor device of claim 11, wherein the source pad and the gate pad are located on the second major surface of the support substrate, and wherein the drain pad is located on the Group III nitride barrier layer.

18. The Group III nitride transistor device of claim 17, further comprising:
one or more electrically conductive vias extending between the source pad that is located on the second major surface of the support substrate and a source bus that is located on the Group III nitride barrier layer.

19. The Group III nitride transistor device of claim 11, wherein the drain pad and the gate pad are located on the Group III nitride barrier layer, and wherein the source pad is located on the second major surface of the support substrate.

20. The Group III nitride transistor device of claim 19, further comprising:
one or more electrically conductive vias extending between the source pad located on the second major surface of the support substrate and a source bus that is located on the Group III nitride barrier layer.
